(19) United States
(12) Patent Application Publication
(10) Pub. No.: US 2018/0130826 A1
(43) Pub. Date: May 10, 2018

(54) METHOD OF MANUFACTURING TOP-GATE THIN FILM TRANSISTOR AND TOP-GATE THIN FILM TRANSISTOR THEREOF

(71) Applicant: Shenzhen China Star Optoelectronics Technology Co. Ltd., Shenzhen (CN)

(72) Inventor: Hejing ZHANG, (US)

(21) Appl. No.: 15/325,443

(22) PCT Filed: Dec. 28, 2016
(86) PCT No.: PCT/CN2016/112541

§ 371 Date: Jan. 11, 2017

(30) Foreign Application Priority Data
Nov. 8, 2016 (CN) 201610979889.1

(51) Int. Cl. H01L 27/12; H01L 29/66; H01L 29/786; H01L 29/45; H01L 29/49

(52) U.S. Cl. CPC H01L 27/1248; H01L 27/1259; H01L 29/66742; H01L 29/78651; H01L 29/458; H01L 29/4908; H01L 29/7869

(57) ABSTRACT

A method of manufacturing a top-gate thin film transistor and a top-gate thin film transistor thereof are described. The method of manufacturing a top-gate thin film transistor includes providing a glass substrate; forming an oxide semiconductor layer on the glass substrate, wherein the oxide semiconductor layer comprises a source region, a drain region and a channel region; forming a gate insulation layer on the oxide semiconductor layer corresponding to a position of the channel region; forming a gate electrode on the gate insulation layer; depositing an interlayer dielectric layer a surface of the gate electrode, a surface of the oxide semiconductor layer, and a surface of the glass substrate by a chemical vapor deposition method; forming a source electrode and a drain electrode, wherein the source electrode and the drain electrode are electrically connected to the source region and the drain region of the oxide semiconductor layer.

### BACKGROUND OF THE INVENTION

### Field of Invention

The present invention relates to a technical field of a liquid crystal display (LCD), and more particularly to a method of manufacturing a top-gate thin film transistor and a top-gate thin film transistor thereof.

### Description of Prior Art

In a conventional electronic device with high resolution and frame, it is required to transform sub-pixels at enough response time for each of thin film transistors (TFTs) in each sub-pixel. Thus, there is a need to prepare the TFTs with the characteristics of lower parasitic capacitance and high mobility. Due to higher mobility, an oxide semiconductor TFT raises much attention. However, the oxide semiconductor TFT adopts conventional bottom gate including ESL and BCE structures, and conventional top-gate type structure. Since the above-mentioned TFT with these structures has a greater parasitic capacitance and these TFTs cannot be easily downsized, the structures are not increasingly applicable to a display apparatus with a large size and a high resolution. Thus, the self-alignment to-gate TFT is particularly important in the display apparatus with the large size and the high resolution.

FIG. 1 is an illustrative view of a conventional self-alignment top-gate thin film transistor. A stop layer 11 is formed on a surface of the glass substrate 10 and an oxide semiconductor layer 12 is formed on the stop layer 11. A gate insulation layer 13 and a gate electrode 14 are formed on the oxide semiconductor layer 12. An interlayer dielectric 16 is disposed on the stop layer 11, the oxide semiconductor layer 12, and the gate electrode 14. A source and drain electrode 15 is disposed on two sides of the gate electrode 14 respectively and are electrically connected to the oxide semiconductor layer 12. In order to reduce the contact resistance between the source and drain electrode 15 and the channel of the oxide semiconductor layer 12, a semiconductor process is performed on the oxide semiconductor layer 12 between the source and drain electrode 15 and the gate electrode 14 to form a conductive layer. As shown in FIG. 1, it is required to make the semiconductor process on the length d of the oxide semiconductor layer 12.

During the semiconductor process technique, some gases, such as H₂, NH₃, CF₄, SF₆, He, Ar, and N₂, are used to perform a surface processing of oxide semiconductor layer 12. However, these gases may raise the introduction of impurity gases, such as ions H and F, where these ions are diffused to the oxide semiconductor layer 12 during the subsequent processes, which disadvantageously affect the properties of the TFT. Furthermore, if the inert gases are used, the semiconductive effect of oxide semiconductor layer 12 cannot be achieved so that the contact resistance between the source and drain electrode 15 and the channel of the oxide semiconductor layer 12 is very high, resulting in a problem of a lower on-state current of the TFT.

Consequently, there is a need to develop a manufacturing method of reducing the contact resistance between the source and drain electrode 15 and the channel of the oxide semiconductor layer 12.

### SUMMARY OF THE INVENTION

Therefore, one objective of the present invention is to provide method of manufacturing a top-gate thin film transistor and a top-gate thin film transistor thereof to perform a conductive process while depositing an interlayer dielectric to increase the mobility and on-state current.

Based on the above objective, the present invention sets forth the following technical solutions. The present invention provides a method of manufacturing a top-gate thin film transistor, including providing a glass substrate;

forming an oxide semiconductor layer on the glass substrate, wherein the oxide semiconductor layer comprises a source region, a drain region and a channel region; forming a gate insulation layer on the oxide semiconductor layer corresponding to a position of the channel region; forming a gate electrode on the gate insulation layer; depositing an interlayer dielectric layer a surface of the gate electrode, a surface of the oxide semiconductor layer, and a surface of the glass substrate by a chemical vapor deposition method, wherein the surfaces of source region and drain region are performed by a conductive process; forming a source electrode and a drain electrode, wherein the source electrode and the drain electrode are electrically connected to the source region and the drain region of the oxide semiconductor layer.

In one embodiment, before forming the oxide semiconductor layer, further comprising forming a stop layer on a surface of the glass substrate wherein the oxide semiconductor layer is formed on the stop layer.

In one embodiment, a material of the interlayer dielectric layer is silicon oxide (SiO₂).

In one embodiment, when performing the chemical vapor deposition, the dissociated ions are configured to bombard the surfaces of the source region and the drain region of the oxide semiconductor layer at a high energy state so that the surfaces of the source region and the drain region of the oxide semiconductor layer can be conductive.

In one embodiment, forming the source electrode and the drain electrode includes forming a plurality of vias on the interlayer dielectric layer, wherein the vias expose the source region and the drain region of the oxide semiconductor layer; and depositing a metal in the vias to form the source electrode electrically connected to the source region and the drain electrode electrically connected to the drain region.

In one embodiment, in view of display apparatus production line in or under the sixth generation of TFT, the power of chemical vapor deposition is greater than 1900 W, and in view of display apparatus production line above the sixth generation of TFT, the power of chemical vapor deposition is greater than 13000 W.

The present invention further provides a top-gate thin film transistor, comprising a glass substrate, a stop layer disposed on a surface of the glass substrate, and an oxide semiconductor layer disposed on a surface of the stop layer, wherein the oxide semiconductor layer comprises a source region, a drain region and a channel region, and a gate insulation layer and a gate electrode are formed on the channel region, wherein an interlayer dielectric layer is formed on the surfaces of the glass substrate, the oxide semiconductor layer and gate electrode, wherein a source electrode and a drain electrode are formed two sides of the gate electrode respectively, and wherein by electrically connecting the vias of the interlayer dielectric layer to the source region and the drain region of the oxide semiconductor layer, the surfaces of the drain region of the oxide semiconductor layer are conductive.

In one embodiment, a material of the interlayer dielectric layer is silicon oxide (SiO₂).

In one embodiment, when performing the chemical vapor deposition, the dissociated ions are configured to bombard the surfaces of the source region and the drain region of the oxide semiconductor layer at a high energy state so that the surfaces of the source region and the drain region of the oxide semiconductor layer can be conductive.

In one embodiment, in view of display apparatus production line in or under the sixth generation of TFT, the power of chemical vapor deposition is greater than 1900 W, and in view of display apparatus production line above the sixth generation of TFT, the power of chemical vapor deposition is greater than 13000 W.

The present invention includes the following advantages.

(1) With respect to mask used in the conventional self-alignment TFT process, is required to perform a conductive process, which resulting in complicated procedure. The present invention can simplify the manufacturing process of the method of manufacturing a top-gate thin film transistor to reduce the complicated process while depositing an interlayer dielectric to increase the mobility and on-state current.

(2) In the conventional technical solutions, the gases are introduced to the conductive process so that the gases are diffused during the subsequent high temperature and thus the process temperature limited. In the present invention, the third party gases are not used and thus the impurity gases are not introduced to prevent the effect of the TFT.

(3) The method of manufacturing a top-gate thin film transistor in the present invention can omits the conductive process to increase the efficiency and save the manufacturing cost.

### BRIEF DESCRIPTION OF THE DRAWINGS

FIG. 1 is an illustrative view of a conventional self-alignment top-gate thin film transistor;

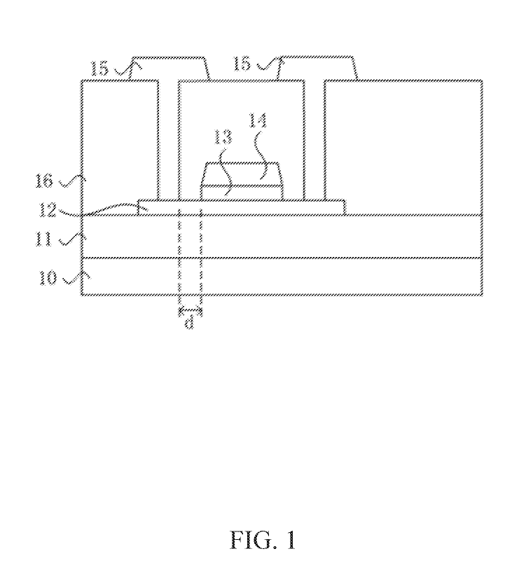

FIG. 2 is a flowchart of manufacturing a top-gate thin film transistor according to one embodiment of the present invention;

FIGS. 3A-3F are illustrative views of manufacturing the top-gate thin film transistor according to one embodiment of the present invention;

FIG. 4 is an illustrative view of the top-gate thin film transistor according to one embodiment of the manufacturing method of the present invention; and

FIG. 5 is a waveform view of the Id-Vg data of the top-gate thin film transistor according to one embodiment of the manufacturing method of the present invention.

### DETAILED DESCRIPTION OF THE PREFERRED EMBODIMENTS

The following embodiments refer to the accompanying drawings for exemplifying specific implementable embodiments of the present invention.

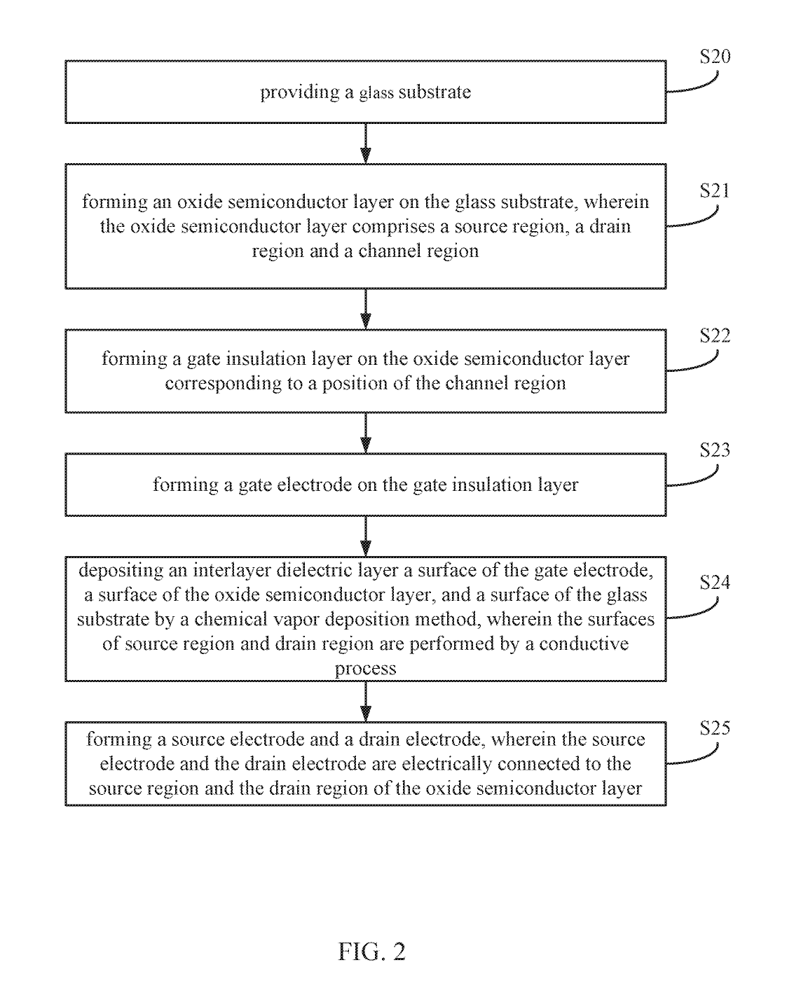

FIG. 2 is a flowchart of manufacturing a top-gate thin film transistor according to one embodiment of the present invention.

In the step S20, a glass substrate is provided.

In the step S21, an oxide semiconductor layer is formed on the glass substrate, where the oxide semiconductor layer includes a source region, a drain region and a channel region.

In the step S22, a gate insulation layer is formed on the oxide semiconductor layer corresponding to a position of the channel region.

In the step S23, a gate electrode is formed on the gate insulation layer.

In the step S24, an interlayer dielectric layer is deposited on a surface of the gate electrode, a surface of the oxide semiconductor layer, and a surface of the glass substrate by a chemical vapor deposition method, where the surfaces of source region and drain region are performed by a conductive process.

In the step S25, a source electrode and a drain electrode are formed, where the source electrode and the drain electrode are electrically connected to the source region and the drain region of the oxide semiconductor layer.

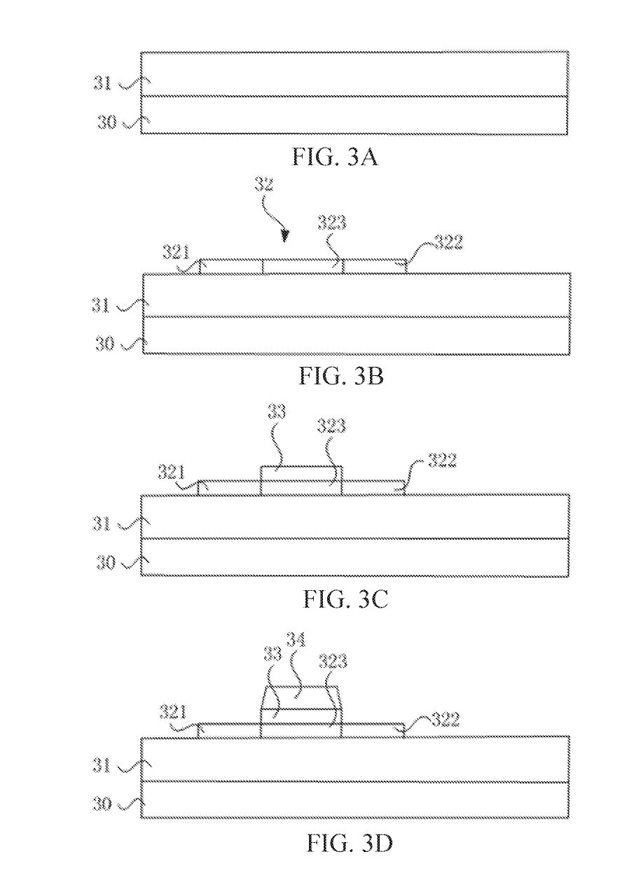

FIGS. 3A-3F are illustrative views of manufacturing the top-gate thin film transistor according to one embodiment of the present invention.

In FIG. 3A and the step S20, a glass substrate 30 is provided. In one embodiment, a stop layer 31 is formed on the glass substrate 30.

In FIG. 3B and the step S21, the oxide semiconductor layer 32 is formed on the substrate 30. In one embodiment, the oxide semiconductor layer 32 is formed on the stop layer 31. The method of forming the oxide semiconductor layer 32 is the same as the method of forming an oxide semiconductor layer of a self-alignment top-gate TFT. The oxide semiconductor layer 32 includes a source region 321, a drain region 322 and a channel region 323.

In FIG. 3C and the step S22, a gate insulation layer 33 is formed on the oxide semiconductor layer 32 corresponding to a position of the channel region 323. In one embodiment, a deposition method is adopted to form the gate insulation layer 33.

In FIG. 3D and the step S23, a gate electrode 34 is formed on the gate insulation layer 33.

In FIG. 3E and the step S24, an interlayer dielectric layer 35 is deposited on a surface of the gate electrode 34, the surfaces of the source region 321 and drain region 322 of the oxide semiconductor layer 32, and a surface of the glass substrate 30 or the stop layer 31 by a chemical vapor deposition method. In one embodiment, the material of the interlayer dielectric layer 35 is silicon oxide (SiO₂).

In view of display apparatus production line in or under the sixth generation of TFT, the power of chemical vapor deposition is greater than 1900 W. In view of display apparatus production line above the sixth generation of TFT, the power of chemical vapor deposition is greater than 13000 W. When performing the chemical vapor deposition, the dissociated ions are configured to bombard the surfaces of the source region 321 and drain region 322 of the oxide semiconductor layer 32 at a high energy state. Since the thickness of the oxide semiconductor layer 32 is smaller and sensitive, the surfaces of the source region 321 and drain region 322 of the oxide semiconductor layer 32 can be conductive to form the conductive layer 39 so that the contact resistance between the source electrode and oxide semiconductor layer 32 is effectively reduced. Meanwhile, the gate electrode and the gate insulation layer can protect the channel region of the oxide semiconductor layer 32 from damage.

In FIG. 3F and the step S25, a source electrode 36 and a drain electrode 37 are formed, where the source electrode 36 and the drain electrode 37 are electrically connected to the source region 321 and the drain region 322 of the oxide semiconductor layer 32. The method of forming the source electrode 36 and the drain electrode 37 includes the following steps.

The vias 38 are formed on the interlayer dielectric layer 35, where the vias 38 expose the source region 321 and the drain region 322 of the oxide semiconductor layer 32. A metal is deposited in the vias 38 to form the source electrode 36 electrically connected to the source region 321 and the drain electrode 37 electrically connected to the drain region 322.

When performing the method of manufacturing top-gate thin film transistor for a self-alignment top-gate TFT process, the conductive process of the semiconductor layer is omitted so that the deposition parameters are easily changed to deposit the interlayer dielectric (ILD) layer by a CVD process, such as SiOₓ, and thus the source region and the drain region can be conductive to increase the mobility and on-state current while depositing the ILD layer.

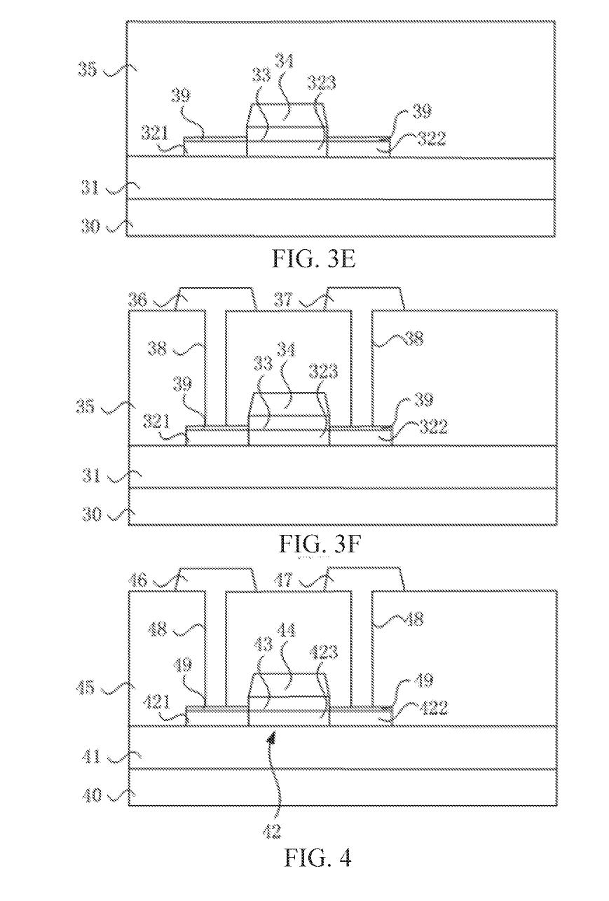

FIG. 4 is an illustrative view of the top-gate thin film transistor according to one embodiment of the manufacturing method of the present invention. The top-gate thin film transistor includes a glass substrate 40, a stop layer 41 disposed on the surface of the glass substrate 40, and an oxide semiconductor layer 42 disposed on the surface of the stop layer 41. The oxide semiconductor layer 42 includes a source region 421, a drain region 422 and a channel region 423. A gate insulation layer 33 and a gate electrode 44 are formed on the channel region 423. An interlayer dielectric layer 45 is formed on the surfaces of the glass substrate 40, the oxide semiconductor layer 42 and gate electrode 44. A source electrode 46 and a drain electrode 47 are formed two sides of the gate electrode 44 respectively. Furthermore, by electrically connecting the vias 48 of the interlayer dielectric layer 45 to the source region 421 and the drain region 422 of the oxide semiconductor layer 42, the surfaces of the drain region 422 of the oxide semiconductor layer 42 are conductive to form the conductive layer 49.

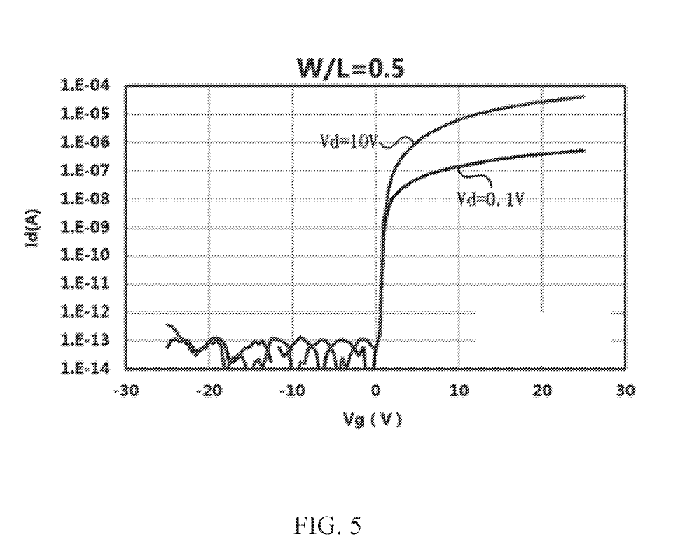

FIG. 5 is a waveform view of the Id-Vg data of the top-gate thin film transistor according to one embodiment of the manufacturing method of the present invention. If W/L is equal to 0.5, the mobility is 16.42. However, if the conventional ILD is used in top-gate TFT, the conventional TFT lacks the semiconductor property.

As is understood by a person skilled in the art, the foregoing preferred embodiments of the present invention are illustrative rather than limiting of the present invention. It is intended that they cover various modifications and similar arrangements be included within the spirit and scope of the present invention, the scope of which should be accorded the broadest interpretation so as to encompass all such modifications and similar structures.

What is claimed is:

1. A method of manufacturing a top-gate thin film transistor, comprising:
providing a glass substrate;
forming a stop layer on a surface of the glass substrate;
forming an oxide semiconductor layer on the stop layer, wherein the oxide semiconductor layer comprises a source region, a drain region and a channel region;
forming a gate insulation layer on the oxide semiconductor layer corresponding to a position of the channel region;
forming a gate electrode on the gate insulation layer;
depositing an interlayer dielectric layer a surface of the gate electrode, a surface of the oxide semiconductor layer, and a surface of the glass substrate by a chemical vapor deposition method, wherein the surfaces of source region and drain region are performed by a conductive process, a material of the interlayer dielectric layer is silicon oxide (SiO₂), when performing the chemical vapor deposition, the dissociated ions are configured to bombard the surfaces of the source region and the drain region of the oxide semiconductor layer at a high energy state so that the surfaces of the source region and the drain region of the oxide semiconductor layer can be conductive, and wherein in view of display apparatus production line in or under the sixth generation of TFT, the power of chemical vapor deposition is greater than 1900 W, and in view of display apparatus production line above the sixth generation of TFT, the power of chemical vapor deposition is greater than 13000 W.

2. A method of manufacturing a top-gate thin film transistor, comprising:
providing a glass substrate;
forming an oxide semiconductor layer on the glass substrate, wherein the oxide semiconductor layer comprises a source region, a drain region and a channel region;
forming a gate insulation layer on the oxide semiconductor layer corresponding to a position of the channel region;
forming a gate electrode on the gate insulation layer;
depositing an interlayer dielectric layer a surface of the gate electrode, a surface of the oxide semiconductor layer, and a surface of the glass substrate by a chemical vapor deposition method, wherein the surfaces of source region and drain region are performed by a conductive process;
forming a source electrode and a drain electrode, wherein the source electrode and the drain electrode are electrically connected to the source region and the drain region of the oxide semiconductor layer.

3. The method of manufacturing the top-gate thin film transistor of claim 2, before forming the oxide semiconductor layer, further comprising forming a stop layer on a surface of the glass substrate wherein the oxide semiconductor layer is formed on the stop layer.

4. The method of manufacturing the top-gate thin film transistor of claim 2, wherein a material of the interlayer dielectric layer is silicon oxide (SiO₂).

5. The method of manufacturing the top-gate thin film transistor of claim 2, wherein when performing the chemical vapor deposition, the dissociated ions are configured to bombard the surfaces of the source region and the drain region of the oxide semiconductor layer at a high energy state so that the surfaces of the source region and the drain region of the oxide semiconductor layer can be conductive.

6. The method of manufacturing the top-gate thin film transistor of claim 2, wherein forming the source electrode and the drain electrode comprises:
forming a plurality of vias on the interlayer dielectric layer, wherein the vias expose the source region and the drain region of the oxide semiconductor layer; and
depositing a metal in the vias to form the source electrode electrically connected to the source region and the drain electrode electrically connected to the drain region.

7. The method of manufacturing the top-gate thin film transistor of claim 2, wherein in view of display apparatus production line in or under the sixth generation of TFT, the power of chemical vapor deposition is greater than 1900 W, and in view of display apparatus production line above the sixth generation of TFT, the power of chemical vapor deposition is greater than 13000 W.

8. A top-gate thin film transistor, comprising a glass substrate, a stop layer disposed on a surface of the glass substrate, and an oxide semiconductor layer disposed on a surface of the stop layer, wherein the oxide semiconductor layer comprises a source region, a drain region and a channel region, and a gate insulation layer and a gate electrode are formed on the channel region, wherein an interlayer dielectric layer is formed on the surfaces of the glass substrate, the oxide semiconductor layer and gate electrode, wherein a source electrode and a drain electrode are formed two sides of the gate electrode respectively, and wherein by electrically connecting the vias of the interlayer dielectric layer to the source region and the drain region of the oxide semiconductor layer, the surfaces of the drain region of the oxide semiconductor layer are conductive.

9. The top-gate thin film transistor of claim 8, wherein a material of the interlayer dielectric layer is silicon oxide (SiO₂).

10. The top-gate thin film transistor of claim 8, wherein when performing the chemical vapor deposition, the dissociated ions are configured to bombard the surfaces of the source region and the drain region of the oxide semiconductor layer at a high energy state so that the surfaces of the source region and the drain region of the oxide semiconductor layer can be conductive.

11. The top-gate thin film transistor of claim 10, wherein in view of display apparatus production line in or under the sixth generation of TFT, the power of chemical vapor deposition is greater than 1900 W, and in view of display apparatus production line above the sixth generation of TFT, the power of chemical vapor deposition is greater than 13000 W.
